(19) United States
(12) Patent Application Publication
(10) Pub. No.: US 2008/0203571 A1
(43) Pub. Date: Aug. 28, 2008

(54) BACKSIDE METALLIZATION FOR INTEGRATED CIRCUIT DEVICES

(76) Inventors: Gotthard Jungnickel, Radeberg (DE); Frank Kuechenmeister, Dresden (DE); Frank Dietrich, Dresden (DE)

Correspondence Address: WILLIAMS, MORGAN & AMERSON, 10333 RICHMOND, SUITE 1100, HOUSTON, TX, 77042, US

(21) Appl. No.: 11/680,353

(22) Filed: Feb. 28, 2007

(51) Int. Cl. H01L 21/44; H01L 23/48

(52) U.S. Cl. 257/751; 438/653; 257/E23.01; 257/E21.476

(57) ABSTRACT

A method of forming backside metallization on a substrate that includes a plurality of integrated circuit die formed on a front side of the substrate is disclosed. The method includes forming an adhesion layer of aluminum or an aluminum alloy on a backside surface of the substrate, forming a barrier metal layer on the adhesion layer and forming a metal layer on the barrier metal layer. An integrated circuit device is also disclosed which includes a substrate having an integrated circuit die formed on a front side of the substrate, an adhesion layer on a backside surface of the substrate, wherein the adhesion layer is aluminum or an aluminum alloy, a barrier metal layer on the adhesion layer and a metal layer on the barrier metal layer.

### BACKGROUND OF THE INVENTION

1. Field of the Invention

The present subject matter is generally directed to the field of semiconductor manufacturing, and, more particularly, to improved backside metallization for integrated circuit devices.

2. Description of the Related Art

The manufacturing of semiconductor devices may involve many process steps. For example, semiconductor fabrication typically involves processes such as deposition processes, etching processes, thermal growth processes, various heat treatment processes, ion implantation, photolithography, etc. Such processes may be performed in any of a variety of different combinations to produce semiconductor devices that are useful in a wide variety of applications.

In general, there is a constant drive within the semiconductor industry to increase the operating speed and efficiency of various integrated circuit devices, e.g., microprocessors, memory devices, and the like. This drive is fueled by consumer demands for computers and electronic devices that operate at increasingly greater speeds and efficiency. This demand for increased speed and efficiency has resulted in a continual reduction in the size of semiconductor devices, e.g., transistors, as well as the packing density of such devices on an integrated circuit device. That is, many components of a typical field effect transistor (FET), e.g., channel length, junction depths, gate insulation thickness, and the like, are reduced. For example, all other things being equal, the smaller the channel length of the transistor or the thinner the gate insulation layer, the faster the transistor will operate. Thus, there is a constant drive to reduce the size, or scale, of the components of a typical transistor to increase the overall speed of the transistor, as well as integrated circuit devices incorporating such transistors. Manufacturing integrated circuit devices is a very complex and competitive business. Customers frequently demand that successive products, or versions thereof, have increased performance capabilities relative to prior products or versions.

In modern integrated circuit devices, heat build-up during operation can be detrimental to device performance. For example, modern integrated circuit devices, e.g., microprocessors, are very densely packed and operate at very high frequencies. As a result, heat is generated during the operation of such devices. Semiconductor manufacturers attempt to dissipate the heat generated during operation by a variety of techniques that typically involve applying a conductive layer to the backside of the substrate. This conductive layer provides a conductive thermal path that may be used to dissipate the heat generated by the integrated circuit device during operation.

FIG. 1 depicts an illustrative prior art technique that is employed in an effort to dissipate the heat generated by an integrated circuit device during operation. As schematically depicted therein, a plurality of integrated circuit devices 18 are formed on a front side 20 of a semiconducting substrate 10. A plurality of metal layers 12, 14, 16 are formed above a backside surface 13 of the substrate 10. In one example, the layers 12, 14, 16 are comprised of titanium (Ti), nickel-vanadium (NiV) and gold (Au), respectively, or alloys thereof.

Ultimately, a singulating process will be performed along illustrative cut lines 22 to separate the integrated circuit devices 18 from one another. Thereafter, traditional packaging techniques may be employed to package the integrated circuit device 18 in an arrangement in which it may be sold. Such traditional packaging methods may involve the attachment of a conductive layer (not shown) above the layer 16 after the substrate 10 has been singulated.

One problem associated with backside metallization techniques, like that depicted in FIG. 1, is contamination of the integrated circuit device 18 or the components on the front side 20 of the substrate 10 that results from cutting through the layers 12, 14 and 16. Obviously, the presence of even small amounts of metal contaminants on the front side of the substrate 10 may be detrimental to the ultimate performance of the complete device. Additionally, using metallization schemes like that depicted in FIG. 1 are believed to require tight control of the backside surface 13 of the substrate 10. For example, it is believed that the surface 13 may be subjected to one or more oxidation processes, chemical mechanical polishing processes or the like, prior to the formation of the layers 12, 14 and 16. Such additional processing that may be performed to condition the backside surface 13 are time-consuming and add to the overall cost of the finished integrated circuit product.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In one illustrative embodiment, a method of forming backside metallization on a substrate that includes a plurality of integrated circuit die formed on a front side of the substrate is disclosed. The method includes forming an adhesion layer of aluminum or an aluminum alloy on a backside surface of the substrate, forming a barrier metal layer on the adhesion layer and forming a metal layer on the barrier metal layer. In some cases, two barrier metal layers may be formed above the adhesion layer.

In another illustrative embodiment, an integrated circuit device is disclosed which includes a substrate having an integrated circuit die formed on a front side of the substrate, an adhesion layer on a backside surface of the substrate, wherein the adhesion layer is aluminum or an aluminum alloy, a barrier metal layer on the adhesion layer and a metal layer on the barrier metal layer. In some cases, two barrier metal layers may be formed above the adhesion layer.

### BRIEF DESCRIPTION OF THE DRAWINGS

The disclosure may be understood by reference to the following description taken in conjunction with the accompanying drawings, in which like reference numerals identify like elements, and in which:

FIG. 1 is a schematic depiction of a prior art backside metallization structure;

FIG. 2 is a schematic depiction of a backside metallization structure as described herein;

FIG. 3 is a schematic depiction of an illustrative integrated circuit with a backside metallization structure described herein;

FIG. 4 is a schematic depiction of another illustrative integrated circuit with a backside metallization structure described herein; and

FIG. 5 is a schematic depiction of yet another illustrative integrated circuit with a backside metallization structure described herein.

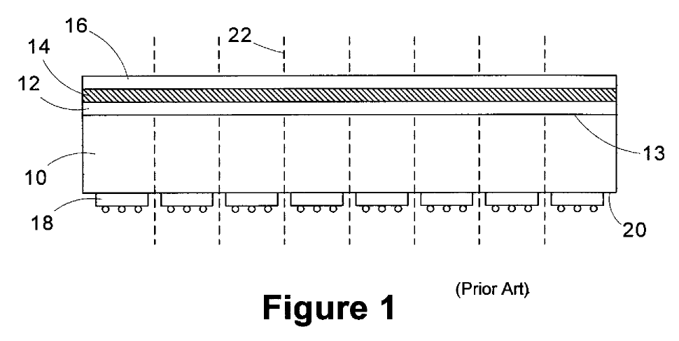

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

FIG. 2 depicts an illustrative embodiment of a backside metallization structure (BSM) 140 disclosed herein. As shown therein, a substrate 112 has a plurality of integrated circuit devices 118 formed above a front surface 120 of the substrate 112. A plurality of illustrative solder balls 128 are formed on each of the integrated circuit devices 118 using traditional techniques. A plurality of layers are formed on and above the backside surface 113 of the substrate 112. More specifically, in one illustrative embodiment, an adhesion layer 130, a first barrier metal 132, a second barrier metal 134 and a metal layer 136 are formed above the backside 113 of the substrate 112.

The substrate 112 is intended to be representative in nature in that it may represent any type of structure upon which the integrated circuit devices 118 may be formed. For example, the substrate 112 may be comprised of silicon, and it may be in the form of a bulk silicon wafer or it may have a silicon-on-insulator structure. Thus, the substrate 112 should not be considered as limited to any particular type of substrate material or structure.

Similarly, the integrated circuit devices 118 are intended to be representative of any type of integrated circuit device, e.g., microprocessors, logic devices, application-specific integrated circuits (ASICs), etc. The illustrative solder balls 128 may be formed by a variety of techniques as well, e.g., C4 techniques. However, it should be understood that the present invention is not limited to any particular technique or structure that may be employed to provide a conductive path or structure to the integrated circuit device 118. For example, other contact techniques, e.g., conductive wire bonds, may be employed to connect the integrated circuit device 118 to additional packaging material, e.g., a leadframe.

In one illustrative embodiment, the adhesion layer 130 may be formed on the surface 113 of the substrate 112. Prior to forming the adhesion layer 130, the surface 113 may be subjected to a sufficient cleaning process, e.g., a sputter etch process, to remove contaminants from the backside surface 113. However, the backside surface 113 need not be subjected to an oxidation process or chemical mechanical polishing process, or the like, to condition the surface 113 prior to the formation of the adhesion layer 130. In this sense, the layer 113 is an unconditioned surface although it may be subjected to a cleaning process to remove any contaminants prior to forming the adhesion layer 130. By using the adhesion layer 130, time-consuming and expensive processes associated with conditioning the surface 113 with an oxidation and/or polishing process may be eliminated.

The adhesion layer 130 may be formed by a variety of known techniques. In one illustrative example, the adhesion layer 130 may be formed by performing a physical vapor deposition (PVD) process. In this case, the backside surface 113 may be subjected to a sputter etch process in the same chamber that is employed in forming the adhesion layer 130 so as to remove contaminants from the surface 113. The adhesion layer 130 may be comprised of aluminum or an aluminum alloy, like aluminum-silicon (AlSi), aluminum-silicon-copper (AlSiCu), and it may have a thickness that ranges from approximately 50-1000 nm. In one particularly illustrative example, the adhesion layer 130 may be comprised of an approximately 100 nm thick layer of aluminum-silicon (AlSi) that is formed by a PVD process.

Next, the first barrier layer 132 is formed on the adhesion layer 130. The first barrier layer 132 may be formed by a variety of known techniques. In one illustrative example, the first barrier layer 132 may be formed by performing a physical vapor deposition (PVD) process. The first barrier layer 132 may be comprised of titanium (Ti), a titanium alloy, titanium-nitrogen (TiN), titanium-tungsten (TiW), chromium (Cr), chromium-copper (CrCu) or cobalt (Co), and it may have a thickness that ranges from approximately 25-1000 nm. In one particularly illustrative example, the first barrier layer 132 may be comprised of an approximately 150 nm thick layer of titanium (Ti) that is formed by a PVD process.

Next the second barrier metal layer 134 is formed on the first barrier metal layer 132. The first barrier layer 132 may be formed by a variety of known techniques. In one illustrative example, the second barrier metal layer 134 may be formed by performing a physical vapor deposition (PVD) process. The second barrier metal layer 134 may be comprised of nickel (Ni) or nickel alloys, nickel-vanadium (NiV), nickel-silicon (NiSi) or nickel-tungsten (NiW), and it may have a thickness that ranges from approximately 50-2500 nm. In one particularly illustrative example, the second barrier metal layer 134 may be comprised of an approximately 250 nm thick layer of nickel-vanadium (NiV) that is formed by a PVD process.

Next the metal layer 136 is formed on the second barrier metal layer 134. The metal layer 136 may be formed by a variety of known techniques. In one illustrative example, the metal layer 136 may be formed by performing a physical vapor deposition (PVD) process. The metal layer 136 may be comprised of gold (Au), copper (Cu), platinum (Pt), palladium (Pd), gold-platinum (AuPt), gold-palladium (AuPd), copper-platinum (CuPt), or copper-palladium (CuPd), and it may have a thickness that ranges from approximately 25-500 nm. In one particularly illustrative example, the metal layer 136 may be comprised of an approximately 100 nm thick layer of gold (Au) that is formed by a PVD process.

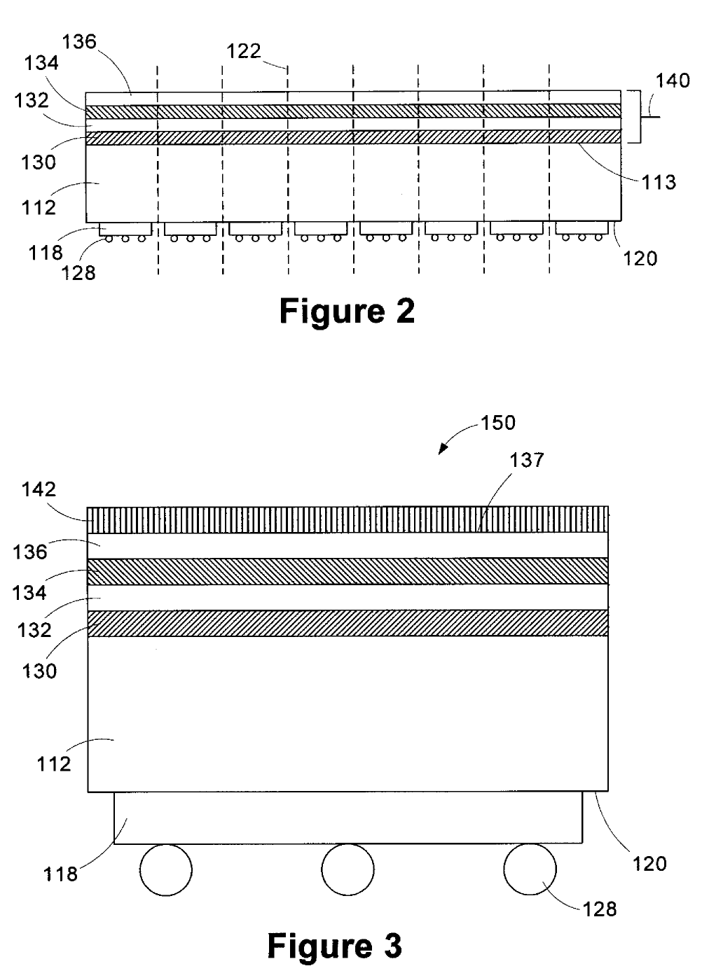

After the layers 130, 132, 134 and 136 are formed, the substrate 112 is then subjected to assembly operations where it will be packaged for sale. More specifically, the substrate 112 may be diced along cut lines 122 to singulate the individual integrated circuit devices 118. FIG. 3 is an enlarged schematic view of an integrated circuit device 118 resulting from the dicing of the substrate 112.

The variety of different processing operations may be performed on the die 150 shown in FIG. 3 as part of the packaging and assembly process. For example, a thermal conduction layer 142 may be formed on or above the metal layer 136. The thermal conduction layer 142 may be comprised of a variety of materials, e.g., a metal, a polymer containing conductive particles, etc. In one particular example, the thermal conduction layer 142 may be comprised of a metal such as indium, gallium, aluminum or any other metal possessing superior heat conductive properties and it may have a thickness of approximately 0.5-2.0 mm. In one particular application, the thermal conduction layer 142 may be provided in a size that corresponds approximately to the size or footprint of the die 150. Such a thermal conduction layer 142 may be attached to the metal layer 136 through use of any of a variety of known techniques, e.g., soldering or a heating process wherein the thermal conduction layer 142 reacts with the metal layer 136. In other cases, where the thermal conduction layer 142 is a polymer material that contains conductive particles, such a material may be directly applied to the surface 137 of the metal layer 136 and thereafter allowed to cure. After the thermal conduction layer 142 is formed and attached to the die 150, any of a variety of additional packaging and assembly operations are performed to complete the packaging of the die 150.

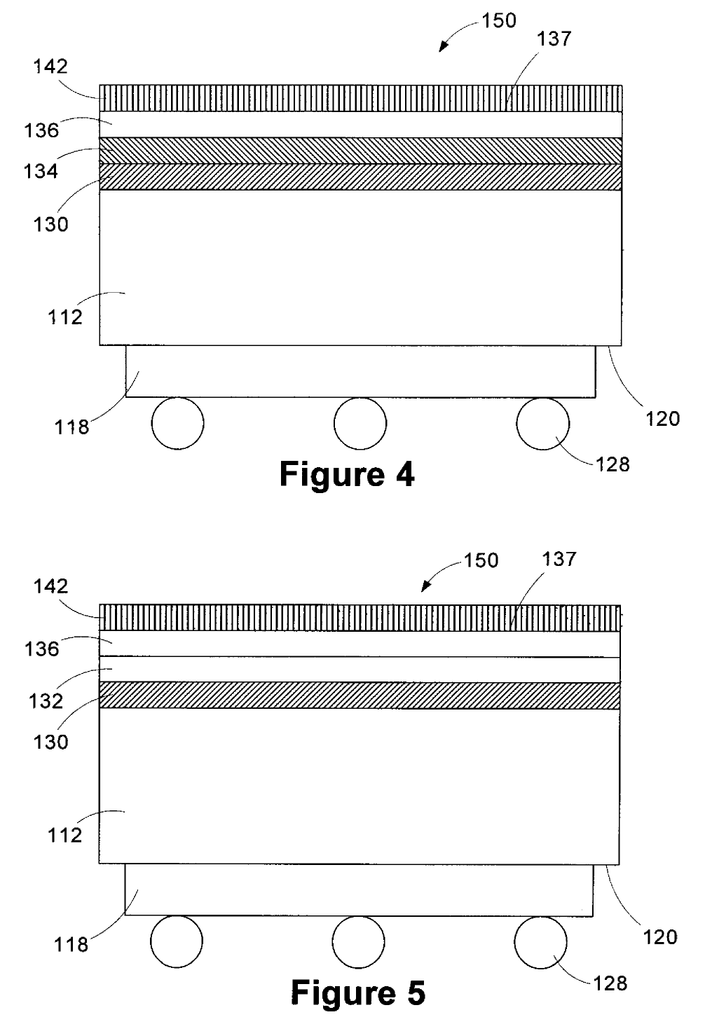

FIGS. 4 and 5 depict other embodiments of the backside metallization structure 140 shown herein. More specifically, the first barrier layer 132 and second barrier layer 134 have been omitted from the device shown in FIGS. 4 and 5, respectively. Depending upon the particular application, and the desired degree of barrier protection, one of the layers 132, 134 may not be required.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method of forming backside metallization on a substrate that comprises a plurality of integrated circuit die formed on a front side of the substrate, the method comprising:
forming an adhesion layer comprised of aluminum or an aluminum alloy on a backside surface of the substrate;
forming a barrier metal layer on the adhesion layer; and
forming a metal layer on the barrier metal layer.

2. The method of claim 1, wherein forming the adhesion layer comprises performing a physical vapor deposition process to form the adhesion layer.

3. The method of claim 1, wherein forming the barrier metal layer comprises performing a physical vapor deposition process to form the barrier layer.

4. The method of claim 1, wherein forming the metal layer comprises performing a physical vapor deposition process to form the metal layer.

5. The method of claim 1, wherein the barrier metal layer comprises at least one of titanium (Ti), a titanium alloy, titanium-nitrogen (TiN), titanium-tungsten (TiW), chromium (Cr), chromium-copper (CrCu), cobalt (Co), nickel (Ni), a nickel alloy, nickel-vanadium (NiV), nickel-silicon (NiSi) and nickel-tungsten (NiW).

6. The method of claim 1, wherein the metal layer comprises at least one of gold (Au), copper (Cu), platinum (Pt), palladium (Pd), gold-platinum (AuPt), gold-palladium (AuPd), copper-platinum (CuPt) and copper-palladium (CuPd).

7. The method of claim 1, wherein, prior to forming the adhesion layer, the method further comprises performing a dry etching process on the backside surface of the substrate.

8. The method of claim 1, wherein said backside surface is an unconditioned surface.

9. The method of claim 1, further comprising performing a dicing process to singulate the plurality of die.

10. The method of claim 9, further comprising forming a thermal conduction layer above the metal layer.

11. The method of claim 9, wherein the thermal conduction layer comprises a metal or metal alloy.

12. The method of claim 9, wherein the thermal conduction layer comprises a polymer material that contains conductive particles.

13. A method of forming backside metallization on a substrate that comprises a plurality of integrated circuit die formed on a front side of the substrate, the method comprising:
forming an adhesion layer comprised of aluminum or an aluminum alloy on a backside surface of the substrate;
forming a first barrier metal layer on the adhesion layer;
forming a second barrier metal layer on the first barrier metal layer; and
forming a metal layer on the second barrier metal layer.

14. The method of claim 13, wherein the first barrier metal layer comprises at least one of titanium (Ti), a titanium alloy, titanium-nitrogen (TiN), titanium-tungsten (TiW), chromium (Cr), chromium-copper (CrCu) and cobalt (Co).

15. The method of claim 13, wherein the second barrier metal layer comprises at least one of nickel (Ni), a nickel alloy, nickel-vanadium (NiV), nickel-silicon (NiSi) and nickel-tungsten (NiW).

16. The method of claim 13, wherein the metal comprises at least one of gold (Au), copper (Cu), platinum (Pt), palladium(Pd), gold-platinum (AuPt), gold-palladium (AuPd), copper-platinum (CuPt) and copper-palladium (CuPd).

17. The method of claim 13, wherein, prior to forming the adhesion layer, the method further comprises performing a dry etching process on the backside surface of the substrate.

18. The method of claim 13, wherein said backside surface is an unconditioned surface.

19. The method of claim 13, further comprising performing a dicing process to singulate the plurality of die.

20. The method of claim 19, further comprising forming a thermal conduction layer above the metal layer.

21. The method of claim 19, wherein the thermal conduction layer comprises a metal or metal alloy.

22. The method of claim 19, wherein the thermal conduction layer comprises a polymer material that contains conductive particles.

23. A method of forming backside metallization on a substrate that comprises a plurality of integrated circuit die formed on a front side of the substrate, the method comprising:
depositing an adhesion layer comprised of aluminum or an aluminum alloy on a backside surface of the substrate;
depositing a first barrier metal layer comprised of titanium on the adhesion layer;
depositing a second barrier metal layer comprised of nickel-vanadium on the first barrier metal layer; and
depositing a metal layer comprised of gold on the second barrier metal layer.

24. The method of claim 23, wherein, prior to depositing the adhesion layer, the method further comprises performing a dry etching process on the backside surface of the substrate.

25. The method of claim 23, wherein said backside surface is an unconditioned surface.

26. The method of claim 23, further comprising performing a dicing process to singulate the plurality of die.

27. The method of claim 26, further comprising forming a thermal conduction layer above the metal layer.

28. The method of claim 26, wherein the thermal conduction layer comprises a metal or metal alloy.

29. The method of claim 26, wherein the thermal conduction layer comprises a polymer material that contains conductive particles.

30. An integrated circuit device, comprising:
a substrate having an integrated circuit die formed on a front side of the substrate;
an adhesion layer on a backside surface of the substrate, wherein the adhesion layer comprises aluminum or an aluminum alloy;
a barrier metal layer on the adhesion layer; and
a metal layer on the barrier metal layer.

31. The device of claim 30, wherein the barrier metal layer comprises at least one of titanium (Ti), a titanium alloy, titanium-nitrogen (TiN), titanium-tungsten (TiW), chromium (Cr), chromium-copper (CrCu), cobalt (Co), nickel (Ni), a nickel alloy, nickel-vanadium (NiV), nickel-silicon (NiSi) and nickel-tungsten (NiW).

32. The device of claim 30, wherein the metal comprises at least one of gold (Au), copper (Cu), platinum (Pt), palladium (Pd), gold-platinum (AuPt), gold-palladium (AuPd), copper-platinum (CuPt) and copper-palladium (CuPd).

33. The device of claim 30, further comprising a thermal conduction layer on the metal layer.

34. The device of claim 33, wherein the thermal conduction layer comprises a metal or metal alloy.

35. The device of claim 33, wherein the thermal conduction layer comprises a polymer material that contains conductive particles.

36. An integrated circuit device, comprising:
a substrate having an integrated circuit die formed on a front side of the substrate;
an adhesion layer on a backside surface of the substrate, wherein the adhesion layer comprises aluminum or an aluminum alloy;
a first barrier metal layer on the adhesion layer;
a second barrier metal layer on the first barrier layer; and
a metal layer on the second barrier metal layer.

37. The device of claim 36, wherein the first barrier metal layer comprises at least one of titanium (Ti), a titanium alloy, titanium-nitrogen (TiN), titanium-tungsten (TiW), chromium (Cr), chromium-copper (CrCu) and cobalt (Co).

38. The device of claim 36, wherein the second barrier metal layer comprises at least one nickel (Ni), a nickel alloy, nickel-vanadium (NiV), nickel-silicon (NiSi) and nickel-tungsten (NiW).

39. The device of claim 36, wherein the metal comprises at least one of gold (Au), copper (Cu), platinum (Pt), palladium (Pd), gold-platinum (AuPt), gold-palladium (AuPd), copper-platinum (CuPt) and copper-palladium (CuPd).

40. The device of claim 36, further comprising a thermal conduction layer on the metal layer.

41. The device of claim 40, wherein the thermal conduction layer comprises a metal or metal alloy.

42. The device of claim 40, wherein the thermal conduction layer comprises a polymer material that contains conductive particles.

43. An integrated circuit device, comprising:
a substrate having an integrated circuit die formed on a front side of the substrate;
an adhesion layer on a backside surface of the substrate, wherein the adhesion layer comprises aluminum or an aluminum alloy;
a first barrier metal layer comprised of titanium on the adhesion layer;
a second barrier metal layer comprised of nickel-vanadium on the first barrier layer; and
a metal layer comprised of gold on the second barrier metal layer.

44. The device of claim 43, further comprising a thermal conduction layer on the metal layer.

45. The device of claim 44, wherein the thermal conduction layer comprises a metal or metal alloy.

46. The device of claim 44, wherein the thermal conduction layer comprises a polymer material that contains conductive particles.
